(19) United States
(12) Patent Application Publication
(10) Pub. No.: US 2026/0282408 A1
(43) Pub. Date: Sep. 17, 2026

(54) SEMICONDUCTOR DEVICE

(71) Applicant: Minebea Power Semiconductor Device Inc., Ibaraki (JP)

(72) Inventor: Yutaka KATO, Ibaraki (JP)

(21) Appl. No.: 19/168,830

(22) PCT Filed: Oct. 25, 2023
(86) PCT No.: PCT/JP2023/038460

§ 371 Date: Sep. 25, 2025

(30) Foreign Application Priority Data
Mar. 31, 2023 (JP) 2023-059266

(51) Int. Cl. H10D 12/00; H10D 64/23

(52) U.S. Cl. CPC H10D 12/481; H10D 64/232

(57) ABSTRACT

The present invention provides a semiconductor device that operates adequately. The semiconductor device includes: a first conductive layer including a drift region; a first insulating layer contacting the first conductive layer; a side gate layer that is formed in an elongated shape, has ends, at least one of which joined to a gate wiring, extends along the first insulating layer, and is configured to apply a voltage to the first conductive layer via the first insulating layer; and a contact layer that is made of a metal-containing material having a lower volume resistivity than the side gate layer and extends in contact with the side gate layer.

### TECHNICAL FIELD

The present invention relates to a semiconductor device.

### BACKGROUND ART

As a background arts of the present technical field, the abstract of Patent Literature 1 describes “adjustment of characteristics of a semiconductor device, such as a turn-on loss”, and the abstract of Patent Literature 2 describes “a semiconductor element with improved electrical characteristics”.

### PRIOR ART LITERATURE

### Patent Literature

Patent Literature 1: Japanese patent application publication No. 2021-122076

Patent Literature 2: Japanese patent application publication No. 2007-273907

### SUMMARY OF THE INVENTION

### Problem to be Solved

In such background arts, there is a demand to operate a semiconductor device more adequately. The present invention is devised in view of such a circumstance and aims to provide a semiconductor device that operates adequately.

### Means to Solve the Problem

To deal with the above issue, a semiconductor device of the present invention includes: a first conductive layer including a drift region; a first insulating layer contacting the first conductive layer; a gate wiring; a side gate layer that is formed in an elongated shape, has ends, at least one of which joined to the gate wiring, extends along the first insulating layer, and is configured to apply a voltage to the first conductive layer via the first insulating layer; and a contact layer that is made of a metal-containing material having a lower volume resistivity than the side gate layer and extends in contact with the side gate layer.

### Advantageous Effects of the Invention

The present invention provides a semiconductor device that operates adequately.

### BRIEF DESCRIPTION OF DRAWINGS

FIG. 1 is a schematic plan view of a semiconductor device according to a first embodiment;

FIG. 2 is an enlarged plan view schematically showing major parts of the semiconductor device; and

FIG. 3 is a cross-sectional view schematically showing the major parts of the semiconductor device.

### EMBODIMENTS OF THE INVENTION

### First Embodiment

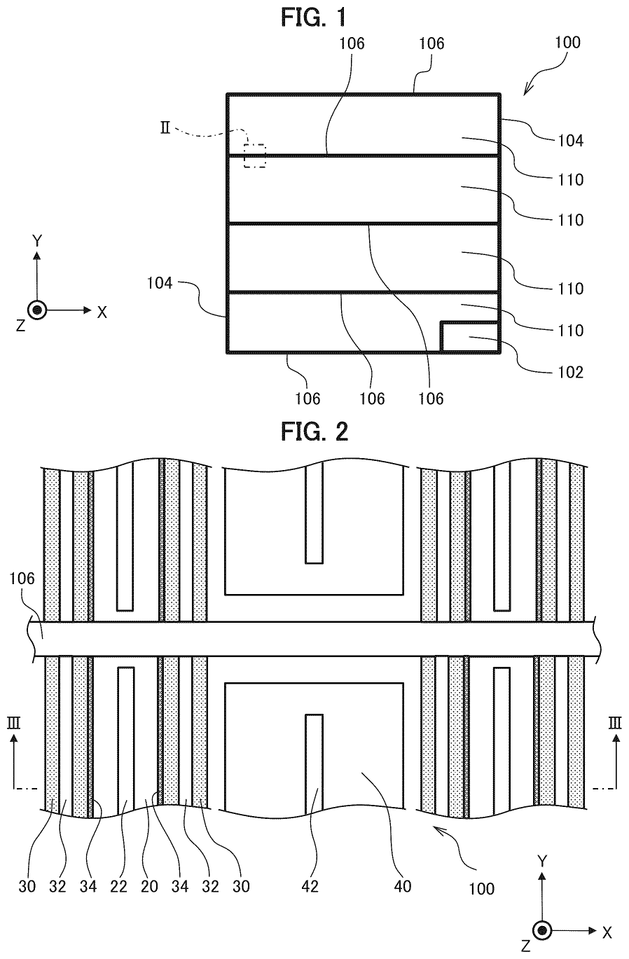

FIG. 1 is a schematic plan view of a semiconductor device 100 of a first embodiment. The semiconductor device 100, which is, for example, an Insulated Gate Bipolar Transistor (IGBT), is formed as a substantially rectangular plate. Axes orthogonal to each other in the surface direction of the semiconductor device 100 are X-axis and Y-axis respectively. An axis in the depth direction of the semiconductor device 100 is a Z-axis. Hereinafter, for convenience, positive and negative directions of X-axis are referred to as “right” and “left” respectively, positive and negative directions of Y-axis are referred to as “front” and “rear” respectively, and positive and negative directions of Z-axis are referred to as “top” and “bottom” respectively. These terms do not denote directions of the semiconductor device 100 being assembled.

The semiconductor device 100 has a right-rear corner formed with a substantially rectangular gate pad 102, and includes gate wirings 104, 106. A pair of gate wirings 104 extends in a front-rear direction along right and left sides of the semiconductor device 100. Two of the five gate wirings 106 extend in a right-left direction along front and rear sides of the semiconductor device 100. The remaining three gate wirings 106 are located respectively at positions where the semiconductor device 100 is divided into nearly quarters in the front-rear direction, and extend in the right-left direction. The gate pad 102 and the gate wirings 104, 106 are connected so as to conduct each other.

The semiconductor device 100 further includes four substantially rectangular emitter electrodes 110 that are insulated from the gate pad 102 and the gate wirings 104, 106 and formed at four areas surrounded by the gate pad 102 and the gate wirings 104, 106. The gate pad 102, the gate wiring 104, 106, and the emitter electrode 110 are made of a metal-containing material. The “metal-containing material” here contains metal in at least some areas, and a type of metal includes aluminum and an alloy of aluminum and silicon, for example.

FIG. 2 is an enlarged plan view schematically showing major parts of the semiconductor device 100, or the enlarged plan view of an active region II of FIG. 1. Here, the “active region” is defined as a region in which an electrical current flows while the semiconductor device 100 is in operation. The semiconductor device 100 further includes a plurality of first conductive layers 20 formed between a pair of neighboring gate wirings 106 in the front-rear direction (see FIG. 1) and positioned at predetermined intervals along the right-left direction. Each first conductive layer 20 is formed in an elongated and substantially rectangular parallelepiped shape, extends in the front-rear direction, and includes a drift region with a first conductive type (P-type, for example).

Further, the first conductive layer 20 has right and left sides each formed with a side gate layer 30 that has an upper surface inclining in a lower-right or lower-left direction. The side gate layer 30 is made of, for example, polysilicon and has a higher volume resistivity than metal-containing materials used in the gate wiring 106. The semiconductor device 100 further includes a first insulating layer 34 disposed between the first conductive layer 20 and the side gate layer 30. The insulating layer 34 is made of an insulating material such as silicon dioxide.

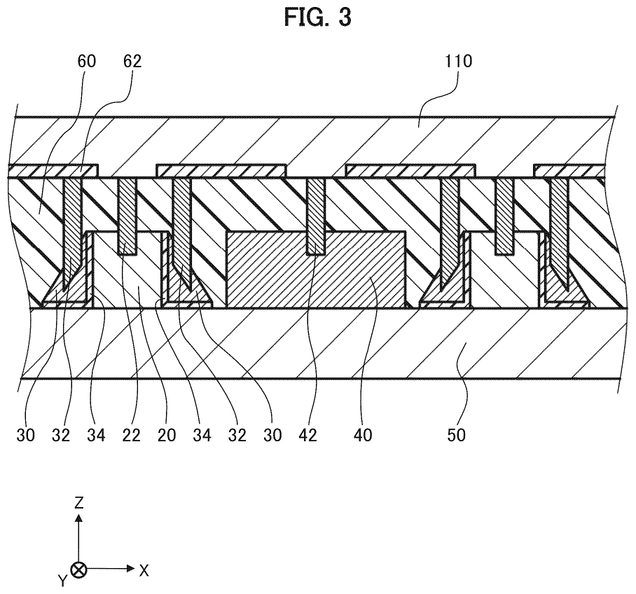

The upper surface of the side gate layer 30 is formed with a contact layer 32 (see FIG. 3) that is formed in a pillared and substantially trapezoidal shape in a cross-sectional view in the front-rear direction. The contact layer 32 has front and rear ends joined to the pair of gate wirings 106. The first conductive layer 20 has an upper surface formed with a substantially rectangular parallelepiped contact layer 22 extending in the front-rear direction. The contact layer 22 has front and rear ends that are spaced from the gate wiring 106 at a predetermined distance.

The semiconductor device 100 further includes a substantially rectangular parallelepiped polysilicon layer 40 positioned at substantially middle of a pair of neighboring first conductive layers 20 in the right-left direction. The polysilicon layer 40 has front and rear ends spaced from the gate wiring 106 at a predetermined distance. The polysilicon layer 40 has an upper surface formed with a substantially rectangular parallelepiped contact layer 42 in the front-rear direction. The contact layers 22, 32, and 42 are made of a metal-containing material.

FIG. 3 is a cross-sectional view schematically showing the major parts of the semiconductor device 100, or a cross-section viewed from a direction of III-III line of FIG. 2. FIG. 3 shows the emitter electrode 110 and other layers positioned below the emitter electrode 110, such as insulating layers. As shown in FIG. 3, the semiconductor device 100 further includes a second conductive layer 50 on which the first conductive layer 20, the side gate layer 30, and the polysilicon layer 40 are disposed. The first insulating layer 34 is positioned between the side gate layer 30 and the first conductive layer 20, and between the side gate layer 30 and the second conductive layer 50.

The second conductive layer 50 is a semiconductor including a drift region with a second conductive type (N-type, for example). The semiconductor device 100 further includes a second insulating layer 60 in which the first conductive layer 20, the side gate layer 30, the polysilicon layer 40, and the contact layers 22, 32, and 42 each formed respectively on the upper surfaces of the layers 20, 30, and 40 are embedded. The second insulating layer 60 is made of an insulating material such as silicon dioxide. As described above, the contact layer 32 is formed in a substantially trapezoidal shape in a cross-sectional view. Particularly, the contact layer 32 has a bottom surface which inclines downward as extending away from the first conductive layer 20.

The contact layers 22, 32, and 42 have upper surfaces exposed from an upper surface of the second conductive layer 60. The upper surface of the second conductive layer 60 is formed with a third conductive layer 62 having a similar insulating material so as to cover the upper surface of the contact layer 32. The emitter electrode 110 is formed so as to cover the upper surfaces of the second insulating layer 60, the third insulating layer 62, and the contact layers 22 and 42. This allows the contact layers 22 and 42 to be joined and conducted to the emitter electrode 110.

The above described contact layers 22, 32, and 42 can be formed after forming the second insulating layer 60. That is, the semiconductor device 100, on which the second insulating layer 60 has been formed, is etched to form contact holes at areas where the contact layers 22, 32, and 42 are to be formed. In such a process, the contact holes are formed to reach predetermined depths from the upper surfaces of the first conductive layer 20, the side gate layer 30, and the polysilicon layer 40.

Next, each contact hole can be filled with the metal-containing material to form the contact layers 22, 32, and 42. The contact layers 22, 32, 42 are formed with the metal-containing material having a lower volume resistivity than the side gate layer 30, such as the aluminum and the alloy of aluminum and silicon described above, and extend in contact with the side gate layer 30. In other words, each of the upper surfaces of the first conductive layer 20, the side gate layer 30, and polysilicon layer 40 are formed in the front-rear direction with groove-like recessed portions (no reference signs) in which the contact layers 22, 32, and 42 are fitted, respectively.

### <Comparison Example>

Next, a comparison example is described to clarify effects of the first embodiment. In a configuration of the comparison example, drawings are omitted but are the same as the drawings used in the first embodiment (see FIGS. 1 to 3) except a configuration of a side gate layer 30 that does not include a contact layer 32. A gate voltage applied to a gate pad 102 is also applied to the side gate layer 30 via gate wirings 104 and 106. However, as the side gate layer 30 includes a material having a higher volume resistivity than a metal-containing material and is formed in an elongated shape in the front-rear direction, the gate voltage is greatly affected by parasitic capacitors of the side gate layer 30 or other layers.

As a result, the side gate layer 30 has a position having a higher resistance viewed from the gate wiring 106 as the position is away from the gate wiring 106. This causes a delay time to transmit the gate voltage to increase, thereby increasing a delay time during a switching operation of a semiconductor device 100.

### <Effects of the Embodiment>

According to the embodiment described above, the semiconductor device 100 includes: the side gate layer 30 that has ends, at least one of which is joined to the gate wiring 106, extends along the first conductive layer 34, and is configured to apply a voltage to the first conductive layer 20 via the first insulating layer 34; and the contact layer 32 that is made of a metal-containing material having a lower volume resistivity than the side gate layer 30 and extends in contact with the side gate layer 30.

This structure allows the semiconductor device 100 to operate adequately. In other words, the structure reduces, by using the contact layer 32, the resistance of the side gate layer 30 from the gate wiring 106 to each portion of the contact layer 32, thereby reducing a delay time during a switching operation of the semiconductor device 100.

Further, the side gate layer 30 is formed with the recessed portion in a direction of extension thereof, and the contact layer 32 is preferably fitted in the recessed portion. This enlarges a contact area between the side gate layer 30 and the contact layer 32, which further reduces the resistance from the gate wiring 106 to each portion of the side gate layer 30.

Further, at least the pair of gate wiring 106 is formed parallel to a predetermined direction (X-axis direction) and the respective ends of the contact layer 32 can be joined to the pair of gate wirings 106. This allows a voltage to be applied to both the ends of the contact layer 32 from the pair of gate wirings 106, thereby further reducing the resistance from the gate wiring 106 to each portion of the side gate layer 30.

Further, the first conductive layer 20 having the drift region with the first conductive type is formed on the surface of the second conductive layer 50 having the drift region with the second conductive type. The first insulating layer 34 is formed extending over the first and second conductive layers 20, 50. The side gate layer 30 is preferably configured to apply the voltage to both the first and second conductive layers 20, 50 via the first insulating layer 34. This allows the voltage to be applied from the gate wiring 106 to both the first and second conductive layers 20, 50 via the contact layer 32.

### <Modifications>

The present invention is not limited to the embodiment described above and allows various modifications. The embodiment has been described for the purpose of illustration and the present invention is not necessarily limited to a structure including all the configurations described above. Further, the configuration of the embodiment can be partly added to or partly replaced with other configurations. Furthermore, control lines and information lines shown in the drawings are lines considered necessary for the purpose of illustration but may not represent all control and information lines required in products. In actual configurations, it can be considered that almost all configurations connect to one another. Examples of possible modifications to the above embodiment include followings.
1. The embodiment has described the semiconductor device 100 employing an IGBT. However, the present invention is not limited to an IGBT and may employ other semiconductor devices to which the side gate layer 30 is applicable, such as a Field-Effect Transistor (FET).
2. The embodiment has described the first conductive type employing “P-type” and the second conductive type employing “N-type”. On the contrary to this, a semiconductor device can employ “N-type” as the first conductive type and “P-type” as the second conductive type.
3. In the embodiment, the front and rear ends of the contact layer 32 are joined to the pair of gate wirings 106, respectively. However, only one of the front and rear ends of the contact layer 32 can be joined to the one of the pair of gate wirings 106.

### LIST OF REFERENCE SIGNS

20 first conductive layer
30 side gate layer
32 contact layer
34 first insulating layer
50 second conductive layer
100 semiconductor device
106 gate wiring

1. A semiconductor device comprising:
a first conductive layer comprising a drift region;
a first insulating layer contacting the first conductive layer;
a gate wiring;
a side gate layer that is formed in an elongated shape; has ends, at least one of which joined to the gate wiring; extends along the first insulating layer; and is configured to apply a voltage to the first conductive layer via the first insulating layer; and
a contact layer that is made of a metal-containing material having a lower volume resistivity than the side gate layer and extends in contact with the side gate layer.

2. The semiconductor device according to claim 1, wherein
the side gate layer is formed with a recessed portion in a direction of extension thereof, and
the contact layer is fitted in the recessed portion.

3. The semiconductor device according to claim 2, wherein
the gate wiring comprises at least a pair of gate wirings which are formed parallel to a predetermined direction, and
the contact layer has both ends joined to the pair of gate wirings, respectively.

4. The semiconductor device according to claim 3, further comprising a second conductive layer, wherein
the first conductive layer is formed on a surface of the second conductive layer,
the first conductive layer includes the drift region of a first conductive type,
the second conductive layer includes a drift region of a second conductive type,
the first insulating layer is formed extending over the first conductive layer and the second conductive layer, and
the side gate layer is configured to apply a voltage to both the first conductive layer and the second conductive layer via the first insulating layer.
